(19) United States
(12) Patent Application Publication
(10) Pub. No.: US 2023/0374219 A1
(43) Pub. Date: Nov. 23, 2023

(54) OPTICAL FILM INCLUDING POLYMER RESIN HAVING EXCELLENT DEGREE OF POLYMERIZATION, AND DISPLAY DEVICE INCLUDING SAME

(71) Applicant: KOLON INDUSTRIES, INC., Seoul (KR)

(72) Inventors: Doo Li CHOI, Seoul (KR); Hak-Gee JUNG, Seoul (KR); Hyo Jun PARK, Seoul (KR)

(21) Appl. No.: 18/247,520

(22) PCT Filed: Dec. 24, 2021
(86) PCT No.: PCT/KR2021/019825

§ 371 Date: Mar. 31, 2023

(30) Foreign Application Priority Data
Dec. 31, 2020 (KR) 10-2020-0188964
Dec. 23, 2021 (KR) 10-2021-0186076

(51) Int. Cl. C08G 73/10; C08J 5/18; H05K 5/03; H10K 59/80

(52) U.S. Cl. CPC C08G 73/1042; C08G 73/1064; C08G 73/1039; C08G 73/1067; C08G 73/1078; C08J 5/18; H05K 5/03; H10K 59/873; C08J 2379/08

(57) ABSTRACT

The present invention provides an optical film and a display device including same, the optical film comprising a polymer resin which includes: a first repeating unit; a second repeating unit; a third repeating unit; and a fourth repeating unit, wherein the first repeating unit is an imide repeating unit derived from a first diamine-based compound and a dianhydride-based compound, the second repeating unit is an imide repeating unit derived from a second diamine-based compound and a dianhydride-based compound, the third repeating unit is an amide repeating unit derived from a first diamine-based compound and a dicarbonyl-based compound, and the fourth repeating unit is an amide repeating unit derived from a second diamine-based compound and a dicarbonyl-based compound. The first diamine-based compound is 2,2′-Bis(trifluoromethyl)benzidine (TFDB), the second diamine-based compound includes aromatic diamine-based compounds, and the number of amide repeating units including the third repeating unit and the fourth repeating unit is at least 80% of the total number of repeating units including the first to fourth repeating units.

### TECHNICAL FIELD

The present disclosure relates to an optical film containing a polymer resin having a high degree of polymerization, and a display device including the same.

### BACKGROUND ART

Recently, the use of an optical film instead of glass as a cover window of a display device has been considered with the goal of reducing the thickness and weight of the display device and increasing the flexibility thereof. In order for the optical film to be usable as a cover window of a display device, the optical film needs to have excellent optical and mechanical properties.

Therefore, it is necessary to develop a film that exhibits excellent optical properties as well as superior mechanical properties, such as insolubility, chemical resistance, heat resistance, radiation resistance, and low-temperature characteristics.

Among optical films, polyimide (PI)-based resins have excellent insolubility, chemical resistance, heat resistance, radiation resistance, and low-temperature characteristics, and are used as automobile materials, aviation materials, spacecraft materials, insulating coatings, insulating films, protective films, and the like.

Recently, polyamide-imide-based resins having amide repeating units added to polyimide-based resins have been developed, and films prepared using polyamide-imide-based resins have superior optical properties, as well as excellent mechanical properties, such as excellent insolubility, chemical resistance, heat resistance, radiation resistance, and low-temperature characteristics. Polyamide-imide-based resins may be prepared using a diamine-based compound, a dianhydride-based compound, and a dicarbonyl-based compound as monomers.

However, for example, 2,2′-bis(trifluoromethyl)benzidine (TFDB), when used as the diamine, causes a problem in that, during polymerization of TFDB with a great amount of dicarbonyl-based compound, the dicarbonyl-based compound is gelled due to the rigid structure of TFDB, so the polymerization reaction is insufficient.

Therefore, there is a need to develop a polyamide-imide-based resin having a high degree of polymerization even when a great amount of dicarbonyl-based compound is added.

### DISCLOSURE

### Technical Problem

It is an aspect of the present disclosure to provide an optical film that contains a polymer resin having a high degree of polymerization even when a great amount of dicarbonyl-based compound is added.

It is another aspect of the present disclosure to provide an optical film that exhibits excellent optical properties as well as mechanical properties.

### Technical Solution

In accordance with the present disclosure, the above and other objects can be accomplished by the provision of an optical film containing a polymer resin including a first repeating unit, a second repeating unit, a third repeating unit, and a fourth repeating unit, wherein the first repeating unit is an imide repeating unit derived from a first diamine-based compound and a dianhydride-based compound, the second repeating unit is an imide repeating unit derived from a second diamine-based compound and the dianhydride-based compound, the third repeating unit is an amide repeating unit derived from the first diamine-based compound and a dicarbonyl-based compound, and the fourth repeating unit is an amide repeating unit derived from the second diamine-based compound and the dicarbonyl-based compound, wherein the first diamine-based compound is 2,2′-bis(trifluoromethyl)benzidine (TFDB) and the second diamine-based compound includes an aromatic diamine-based compound, and a sum of numbers of the amide repeating units including the third and fourth repeating units is 80% or more of a total number of repeating units including the first to fourth repeating units.

The aromatic diamine-based compound of the second diamine-based compound may have an ionization energy of 7.35 to 7.75 eV.

The aromatic diamine-based compound of the second diamine-based compound may include at least one functional group selected from the group consisting of sulfonyl, carbonyl, methylene, propylene, and halogens.

The aromatic diamine-based compound of the second diamine-based compound may include at least one selected from the group consisting of bis(3-aminophenyl)sulfone (3DDS), bis(4-aminophenyl)sulfone (4DDS), 2,2-bis(3-aminophenyl)hexafluoropropane (3,3′-6F), 2,2-bis(4-aminophenyl)hexafluoropropane (4,4′-6F), 4,4′-methylenedianiline (MDA), 3,3′-(dimethylamino)benzophenone, 4,4′-(dimethylamino)benzophenone, and tetrachloride benzidine (CIBZ).

A ratio of a number of repeating units derived from the first diamine-based compound to a number of repeating units derived from the second diamine-based compound may be 95:5 to 65:35.

The polymer resin may have a weight average molecular weight (Mw) of 200,000 to 500,000.

The optical film may have a yellowness index (Y.I.) of 3 or less based on a thickness of 50 μm.

The optical film may have a light transmittance of 88% or more based on a thickness of 50 μm.

The optical film may have a haze of 0.5% or less based on a thickness of 50 μm.

In accordance with another aspect of the present disclosure, there is provided a display device including a display panel, and the optical film disposed on the display panel.

### Advantageous Effects

In an embodiment of the present disclosure, an optical film containing a polymer resin having a high degree of polymerization even when a large amount of the dicarbonyl-based compound is added can be provided by controlling the polymerization reaction of the diamine-based compound and the dicarbonyl-based compound.

An embodiment of the present disclosure provides an optical film having excellent optical properties.

The optical film according to another embodiment of the present disclosure exhibits excellent optical and mechanical properties and thus is capable of effectively protecting the display surface of a display device when used as a cover window of the display device.

### DESCRIPTION OF DRAWINGS

FIG. 1 is a cross-sectional view illustrating a part of a display device according to an embodiment of the present disclosure; and

FIG. 2 is an enlarged cross-sectional view illustrating “P” of FIG. 1.

### BEST MODE

Hereinafter, embodiments of the present disclosure will be described in detail with reference to the accompanying drawings. However, the following embodiments are illustratively provided merely for clear understanding of the present disclosure, and do not limit the scope of the present disclosure.

The shapes, sizes, ratios, angles, and numbers disclosed in the drawings for describing embodiments of the present disclosure are merely examples, and the present disclosure is not limited to the illustrated details. Like reference numerals refer to like elements throughout the present specification. In the following description, when a detailed description of relevant known functions or configurations is determined to unnecessarily obscure important points of the present disclosure, the detailed description will be omitted.

In the case in which the term such as “comprise”, “have”, or “include” is used in the present specification, another part may also be present, unless “only” is used. Terms in a singular form may include the plural meanings, unless noted to the contrary. Also, in construing an element, the element is to be construed as including an error range even if there is no explicit description thereof.

In describing a positional relationship, for example, when the positional relationship is described as “on”, “above”, “below”, or “next”, the case of no contact therebetween may be included, unless “just” or “directly” is used.

Spatially relative terms, such as “below”, “beneath”, “lower”, “above”, and “upper”, may be used herein to describe the relationship between a device or element and another device or element, as shown in the figures. It will be understood that spatially relative terms are intended to encompass different orientations of a device during the use or operation of the device, in addition to the orientation depicted in the figures. For example, if a device in one of the figures is turned upside down, elements described as “below” or “beneath” other elements would then be positioned “above” the other elements. The exemplary term “below” or “beneath” can, therefore, encompass the meanings of both “below” and “above”. In the same manner, the exemplary term “above” or “upper” can encompass the meanings of both “above” and “below”.

In describing temporal relationships, for example, when a temporal order is described using “after”, “subsequent”, “next”, or “before”, the case of a non-continuous relationship may be included, unless “just” or “directly” is used.

It will be understood that, although the terms “first”, “second”, etc. may be used herein to describe various elements, these elements are not limited by these terms. These terms are only used to distinguish one element from another. Therefore, a first element could be termed a second element within the technical idea of the present disclosure.

It should be understood that the term “at least one” includes all combinations related with one or more items. For example, “at least one among a first element, a second element, and a third element” may include all combinations of two or more elements selected from among the first, second, and third elements, as well as each of the first, second, and third elements.

Features of various embodiments of the present disclosure may be partially or completely coupled to or combined with each other, and may be variously interoperated with each other and driven technically. The embodiments of the present disclosure may be carried out independently from each other, or may be carried out together in an interrelated manner.

An embodiment of the present disclosure provides an optical film. The optical film according to the embodiment of the present disclosure contains a polymer resin.

The polymer resin may be contained in the film in any one of various shapes and forms, for example, as a solid powder, in the state of being dissolved in a solution, or as a matrix solidified after having been dissolved in a solution. Any resin may be considered as the same as the polymer resin of the present disclosure, regardless of the shape and form thereof, as long as it is a resin containing the same repeating unit as in the present disclosure. In general, the polymer resin may exist in the film in the form of a matrix, obtained by applying a polymer resin solution and drying the same to form a solid.

The optical film according to an embodiment of the present disclosure may include at least one of an imide repeating unit and an amide repeating unit. For example, the optical film according to an embodiment of the present disclosure may contain at least one of a polyimide-based polymer, a polyamide-based polymer, and a polyamide-imide-based polymer.

The optical film according to an embodiment of the present disclosure may include an imide repeating unit formed by a diamine-based compound and a dianhydride-based compound.

The optical film according to an embodiment of the present disclosure may include an amide repeating unit formed by a diamine-based compound and a dicarbonyl-based compound.

The optical film according to an embodiment of the present disclosure may include both an amide repeating unit and an imide repeating unit formed by a diamine-based compound, a dianhydride-based compound, and a dicarbonyl-based compound.

For example, the optical film according to an embodiment of the present disclosure may contain at least one of a polyimide-based resin, a polyamide-based resin, and a polyamide-imide-based resin.

According to an embodiment of the present disclosure, the optical film may be any one of a polyimide-based film, a polyamide-based film, and a polyamide-imide-based film, but the embodiments of the present disclosure are not limited thereto. Any film having light transmittance may be used as the optical film according to an embodiment of the present disclosure.

The polymer resin according to an embodiment of the present disclosure includes a first repeating unit, a second repeating unit, a third repeating unit, and a fourth repeating unit.

The first repeating unit is an imide repeating unit derived from a first diamine-based compound and a dianhydride-based compound, the second repeating unit is an imide repeating unit derived from a second diamine-based compound and the dianhydride-based compound, the third repeating unit is an amide repeating unit derived from the first diamine-based compound and a dicarbonyl-based compound, and the fourth repeating unit is an amide repeating unit derived from the second diamine-based compound and the dicarbonyl-based compound.

The sum of numbers of the amide repeating units including the third and fourth repeating units is 80% or more of the total number of repeating units including the first to fourth repeating units.

As used herein, the term “repeating unit derived . . . ” means that multiple monomers for forming a polymer are linked to one another and are repeatedly arranged in the polymer. This term is widely used in the field to which the present disclosure pertains. For example, polyethylene, which is a polymer having repeating units derived from ethylene, has a structure in which multiple ethylene monomers are linked to one another and are repeatedly arranged in a polyethylene polymer.

In the present disclosure, the imide repeating unit of the polymer resin may be prepared from monomer components including a diamine-based compound and a dianhydride-based compound. Specifically, the diamine-based compound and the dianhydride-based compound are polymerized to form amic acid, and the amic acid is imidized to form an imide repeating unit. In addition, the amide repeating unit may also be prepared through polymerization of monomer components including a diamine-based compound and a dicarbonyl-based compound. The specific structures of the imide repeating unit and the amide repeating unit may vary depending on the monomers used for the reaction.

However, the polymer resin according to an embodiment of the present disclosure is not limited thereto. The polymer resin according to an embodiment of the present disclosure may be prepared from monomer components further including other compounds, in addition to the diamine-based compound, the dianhydride-based compound, and the dicarbonyl-based compound. Therefore, the polymer resin according to an embodiment of the present disclosure may further include other repeating units, in addition to the imide repeating unit and the amide repeating unit.

According to an embodiment of the present disclosure, the sum of the number of the amide repeating units including the third and fourth repeating units corresponds to 80% or more of the total number of repeating units including the first to fourth repeating units. Preferably, the sum of the number of the amide repeating units including the third and fourth repeating units corresponds to 95% or more of the total number of repeating units including the first to fourth repeating units, more preferably 98% or more thereof.

When the sum of the numbers of the amide repeating units including the third and fourth repeating units is 80% or more of the total number of repeating units including the first to fourth repeating units, the optical properties of the produced film can be maintained while the mechanical properties thereof can be improved. That is, an optical film that is colorless and transparent, and has improved insolubility, chemical resistance, heat resistance, radiation resistance, low-temperature characteristics, tensile strength, elongation, and the like is produced by including more of the amide repeating units than the imide repeating units.

When a large amount of the dicarbonyl-based compound is added in order to form a large number of amide repeating units, there is a problem in that the dicarbonyl-based compound is gelled and thus the polymerization reaction is insufficiently performed.

In the present disclosure, gelation of the dicarbonyl-based compound can be prevented or inhibited by performing polymerization using two or more different types of diamine-based compounds. Accordingly, the polymer resin of the present disclosure includes repeating units derived from at least two types of diamine-based compounds including the first diamine-based compound and the second diamine-based compound.

Specifically, according to an embodiment of the present disclosure, the first diamine-based compound is 2,2′-bis(trifluoromethyl)benzidine (TFDB), and the second diamine-based compound includes an aromatic diamine-based compound other than TFDB. The imide repeating unit and the amide repeating unit of the present disclosure may be derived from TFDB and an aromatic diamine-based compound other than TFDB.

Since the 2,2′-bis(trifluoromethyl)benzidine (TFDB) of the first diamine-based compound has a specific linear and rigid structure, a film that includes a repeating unit derived from TFDB can be imparted with greatly improved mechanical properties, such as insolubility, chemical resistance, heat resistance, radiation resistance, and low-temperature characteristics.

However, polymerization between TFDB and a dicarbonyl-based compound is accelerated due to the rigid structure of TFDB. Such rapid polymerization may allow only a part of the dicarbonyl-based compound to react with the diamine-based compound, and the remainder of the dicarbonyl-based compound may be gelled rather than being polymerized. The gelation of the dicarbonyl-based compound may reduce the degree of polymerization of the resin and deteriorate the optical properties of the film. Therefore, it is difficult to prepare a polymer resin including a large amount of amide repeating units merely through addition of TFDB. According to the present disclosure, a second diamine-based compound having a predetermined ionization energy can prevent gelation of the dicarbonyl-based compound and improve the polymerization degree of the polymer.

According to an embodiment of the present disclosure, the second diamine-based compound includes an aromatic diamine-based compound.

In an embodiment of the present disclosure, the term “aromatic diamine-based compound” refers to a diamine-based compound in which an amino group is directly bonded to an aromatic ring, and may include an aliphatic group or other substituents as part of the structure thereof. The aromatic ring may be a single ring, a fused ring including a single ring linked thereto directly via a heteroatom, or a condensed ring. Examples of the aromatic ring may include, but are not limited to, a benzene ring, a biphenyl ring, a naphthalene ring, an anthracene ring, and a fluorene ring.

According to an embodiment of the present disclosure, the second diamine-based compound may be represented by the following Formula 1:

H₂N-A′—NH₂ [Formula 1]
wherein A¹ represents a divalent aromatic organic group. The aromatic organic group refers to an organic group in which pi electrons are delocalized, whereby single bonds and double bonds alternately link to each other to form rings. For example, A¹ may include a divalent aromatic organic group having 4 to 40 carbon atoms. A hydrogen atom in the aromatic organic group in Formula 1 may be substituted with a halogen element, a hydrocarbon group, or a hydrocarbon group substituted with a halogen element. Here, the hydrocarbon group or the hydrocarbon group substituted with a halogen element may have 1 to 8 carbon atoms. For example, the hydrogen in A¹ may be substituted with —F, —CH₃, —CF₃, or the like.

An optical film produced using a diamine-based compound in which a hydrogen atom is substituted with a fluorine-substituted hydrocarbon group can be imparted with excellent light transmittance and excellent workability.

A¹ in Formula 1 may, for example, include a structure represented by any one of the following formulas.

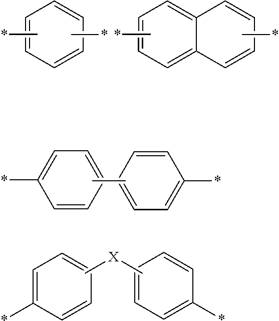

In the above formulas, * represents a bonding position. In the above formulas, X may be any one of a single bond, O, S, SO₂, CO, CH₂, C(CH₃)₂, and C(CF₃)₂. Although the bonding position of X on each ring is not particularly limited, the bonding position of X may be, for example, a meta or para position on each ring.

According to an embodiment of the present disclosure, the second diamine-based compound includes an aromatic diamine-based compound having an ionization energy of 7.35 to 7.75 eV.

Since the second diamine-based compound further includes an aromatic diamine-based compound having an ionization energy of 7.35 to 7.75 eV other than TFDB as the second diamine-based compound, it can be polymerized with a large amount of dicarbonyl-based compound at a high degree of polymerization. When the ionization energy of the aromatic diamine-based compound is 7.35 to 7.75 eV, the polymerization reaction rate of the diamine-based compound and the dicarbonyl-based compound can be controlled, the polymerization reaction can proceed smoothly even if a large amount of the dicarbonyl-based compound is included, and the degree of polymerization of the resin can be improved.

When the ionization energy of the aromatic diamine-based compound of the second diamine-based compound is less than 7.35 eV, the electron donation effect of the diamine-based compound improves and the charge-transfer complex effect thereof increases, thereby causing deterioration of optical properties. In addition, the high reactivity increases the reaction rate, so the dicarbonyl-based compound may be gelled.

On the other hand, when the ionization energy of the aromatic diamine-based compound of the second diamine-based compound exceeds 7.55 eV, the degree of polymerization decreases due to low reactivity. Accordingly, a relatively short polymer chain is formed, and the number of end groups of the polymer chain is increased. When the number of end groups of the polymer chain increases, the physical properties of the resin are deteriorated.

According to an embodiment of the present disclosure, the aromatic diamine-based compound of the second diamine-based compound may include at least one functional group selected from the group consisting of sulfonyl, carbonyl, methylene, propylene, and halogens.

The sulfonyl, carbonyl, methylene, propylene and halogen substituents function to control the movement of electrons in the compound. Accordingly, the second diamine-based compound can be imparted with an ionization energy of 7.35 to 7.75 eV by including at least one substituent of sulfonyl, carbonyl, methylene, propylene, and halogens. As a result, the reactivity and reaction rate of the polymerization reaction with the dicarbonyl-based compound can be appropriately adjusted.

According to an embodiment of the present disclosure, the second diamine-based compound may include at least one selected from the group consisting of bis(3-aminophenyl)sulfone (3DDS), bis(4-aminophenyl)sulfone (4DDS), 2,2-bis(3-aminophenyl)hexafluoropropane (3,3′-6F), 2,2-bis(4-aminophenyl)hexafluoropropane (4,4′-6F), 4,4′-methylenedianiline (MDA), 3,3′-(dimethylamino)benzophenone, 4,4′-(dimethylamino)benzophenone, and tetrachloride benzidine (CIBZ). All of the aromatic diamine-based compounds listed above are diamine-based compounds having an ionization energy of 7.35 to 7.75 eV.

According to an embodiment of the present disclosure, the ratio of the number of repeating units derived from the first diamine-based compound to the number of repeating units derived from the second diamine-based compound (repeating units derived from first diamine-based compound: repeating units derived from second diamine-based compound) may be within the range of 95:5 to 65:35. Here, the term “the repeating unit derived from the first diamine-based compound (or the second diamine-based compound)” is meant to include both the imide repeating unit and the amide repeating unit derived from the first diamine-based compound (or the second diamine-based compound).

When, with regard to “repeating units derived from first diamine-based compound: repeating units derived from second diamine-based compound”, the fraction of the repeating units derived from the first diamine-based compound increases above 95:5, the fraction of the repeating units derived from the TFDB and the dicarbonyl-based compound increases, and haze increases. On the other hand, when the fraction of the repeating units derived from the second diamine-based compound increases above 65:35, the heat resistance and strength of the film may be reduced.

In an embodiment of the present disclosure, the dianhydride-based compound may be represented by the following Formula 2:

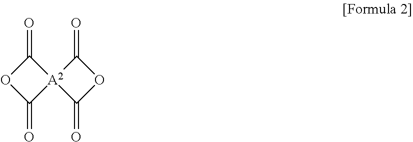

wherein A² represents a tetravalent organic group. For example, A² may include a tetravalent organic group having 4 to 40 carbon atoms. A hydrogen atom in the organic group in Formula 2 may be substituted with a halogen element, a hydrocarbon group, or a hydrocarbon group substituted with a halogen element. Here, the hydrocarbon group or the hydrocarbon group substituted with a halogen element may have 1 to 8 carbon atoms.

A² in Formula 2 may, for example, include a structure represented by any one of the following formulas.

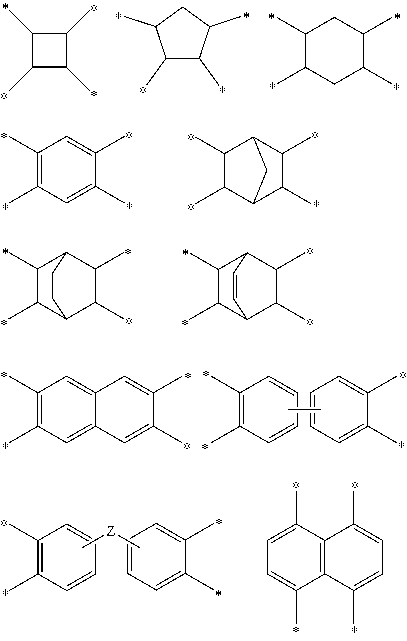

In the above formulas, * represents a bonding position. In the above formulas, Z may independently be any one of a single bond, O, S, SO₂, CO, (CH₂)ₙ, (C(CH₃)₂)ₙ and (C(CF₃)₂)ₙ, and n may be an integer of 1 to 5. Although the bonding position of Z on each ring is not particularly limited, the bonding position of Z may be, for example, a meta or para position on each ring.

In an embodiment of the present disclosure, the dianhydride-based compound may include one or more selected from the group consisting of 2,2-bis(3,4-dicarboxyphenyl)hexafluoropropane dianhydride (6FDA), biphenyl tetracarboxylic dianhydride (BPDA), naphthalene tetracarboxylic dianhydride (NTDA), diphenyl sulfone tetracarboxylic dianhydride (DSDA), 4-(2,5-oxotetrahydrofuran-3-yl)-1,2,3,4-tetrahydronaphthalene-1,2-dicarboxylic anhydride (TDA), pyromellitic dianhydride (PMDA), benzophenone tetracarboxylic dianhydride (BTDA), oxydiphthalic anhydride (ODPA), bis(carboxyphenyl)dimethyl silane dianhydride (SiDA), bis(dicarboxyphenoxy)diphenyl sulfide dianhydride (BDSDA), sulfonyldiphthalic anhydride (SO₂DPA), isopropylidenediphenoxy bis(phthalic anhydride) (BPADA), 1,2,3,4-cyclobutanetetracarboxylic dianhydride, (CBDA), 1,2,3,4-cyclopentanetetracarboxylic dianhydride, (CPDA), 1,2,3,4-cyclohexanetetracarboxylic dianhydride, (CHDA), 1,2,3,4-butanetetracarboxylic dianhydride, 1,2,3,4-tetramethyl-1,2,3,4-cyclobutanetetracarboxylic dianhydride, dicyclohexyl-3,4,3″,4″-tetracarboxylic dianhydride, tetrahydrofuran-2,3,4,5-tetracarboxylic dianhydride, and bicyclo[2.2.2]octane-2,3,5,6-tetracarboxylic 2,3:5,6-dianhydride), but the present disclosure is not limited thereto.

The monomer used in the manufacture of the optical film according to an embodiment of the present disclosure may include, for example, a plurality of kinds of dianhydride-based compounds.

An optical film produced using a dianhydride-based compound in which a hydrogen atom is substituted with a fluorine-substituted hydrocarbon group can be imparted with excellent light transmittance and excellent workability.

According to an embodiment of the present disclosure, the dicarbonyl-based compound may be represented by the following Formula 3:

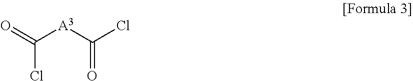

wherein A³ represents a divalent organic group. For example, A³ may include a divalent organic group having 4 to 40 carbon atoms. A hydrogen atom in the organic group in Formula 3 may be substituted with a halogen element, a hydrocarbon group, or a hydrocarbon group substituted with fluorine. Here, the hydrocarbon group or the hydrocarbon group substituted with fluorine may have 1 to 8 carbon atoms. For example, the hydrogen in A³ may be substituted with —F, —CH₃, —CF₃, or the like.

A³ in Formula 3 may, for example, include a structure represented by any one of the following formulas.

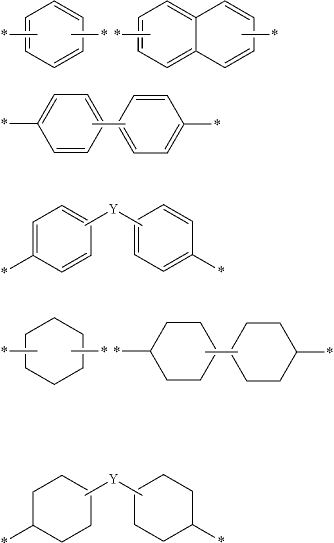

In the above formulas, * represents a bonding position. In the above formulas, Y may independently be any one of a single bond, O, S, SO₂, CO, CH₂, C(CH₃)₂ and C(CF₃)₂. Although the bonding position of Y on each ring is not particularly limited, the bonding position of Y may be, for example, a meta or para position on each ring.

According to an embodiment of the present disclosure, the dicarbonyl-based compound may include at least one selected from the group consisting of terephthaloyl chloride (TPC), isophthaloyl chloride (IPC), biphenyl dicarbonyl chloride (BPDC), 4,4′-oxybis benzoyl chloride (OBBC), and naphthalene dicarbonyl dichloride (NTDC).

The polymer resin according to an embodiment of the present disclosure may include a first repeating unit represented by the following Formula 4 and a second repeating unit represented by the following Formula 5:

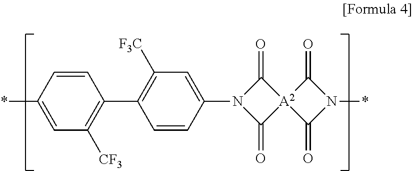

wherein A² is as described above, and

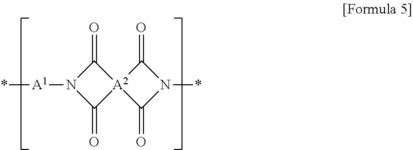

wherein A¹ and A² are as described above.

The polymer resin according to an embodiment of the present disclosure may include a third repeating unit represented by the following Formula 6 and a fourth repeating unit represented by the following Formula 7:

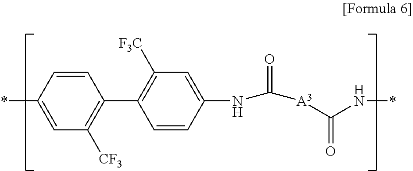

wherein A³ is as described above, and

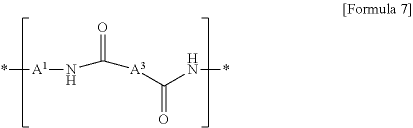

wherein A¹ and A³ are as described above.

According to an embodiment of the present disclosure, the weight average molecular weight (Mw) of the polymer resin of the present disclosure may be 200,000 to 500,000.

The weight average molecular weight of the polymer resin can be measured under the following conditions using GPC (Alliance e2695/2414 RID, Waters).
Detector: 2414 RID, Waters
Mobile phase: 10 mM LiBr in DMAc
Sample concentration: 0.25 (w/w) % in DMAc
Column and detector temperature: 50° C.
Flow Rate: 1.0 ml/min

The gelation of the dicarbonyl-based compound due to the high reaction rate with a diamine-based compound, in particular TFDB, reduces the degree of polymerization of the polymer resin including a large number of amide repeating units. The weight average molecular weight is proportional to the polymerization degree. That is, as the polymerization degree decreases, the weight average molecular weight of the polymer resin also decreases.

When the weight average molecular weight of the polymer resin is less than 200,000, the degree of polymerization decreases, the number of end groups of the polymer chain increases, and the physical properties of the polymer resin are deteriorated. On the other hand, it is difficult to prepare a polymer resin having a weight average molecular weight of more than 500,000 during the process. The weight average molecular weight of the polymer resin is adjusted by controlling the polymerization viscosity during polymerization. A resin having a weight average molecular weight exceeding 500,000 is disadvantageous for processing because of the very high polymerization viscosity and consequent reduced flowability of the reaction solution, which make it difficult to control and handle, and the necessity of a large amount of solvent in order to dissolve the polymer resin again.

According to an embodiment of the present disclosure, the optical film is light-transmissive. In addition, the optical film is flexible. For example, the optical film according to an embodiment of the present disclosure is bendable, foldable, or rollable. The optical film may have excellent mechanical and optical properties.

According to an embodiment of the present disclosure, the optical film may have a thickness sufficient for the optical film to protect the display panel. For example, the optical film may have a thickness of 10 to 100 μm.

According to an embodiment of the present disclosure, the optical film may have an average light transmittance in the visible light region measured using a UV spectrophotometer, of 88% or more based on a thickness of 50 μm.

The average light transmittance of the optical film may be measured in a wavelength range of 360 to 740 nm using a spectrophotometer (CM-3700D, KONICA MINOLTA).

According to an embodiment of the present disclosure, the optical film may have a yellowness index of 3 or less based on a thickness of 50 μm.

The yellowness index of the optical film may be measured using a spectrophotometer (CM-3700D, KONICA MINOLTA) in accordance with the ASTM E313 standard.

According to an embodiment of the present disclosure, the optical film may have a haze of 0.5% or less based on a thickness of 50 μm.

The haze of the optical film may be determined by cutting the produced optical film to a sample having a size of 50 mm×50 mm, performing measurement five times using a haze meter (model name: HM-150, produced by Murakami Color Research Laboratory) in accordance with ASTM D1003, and taking the average of the five values as the haze of the optical film.

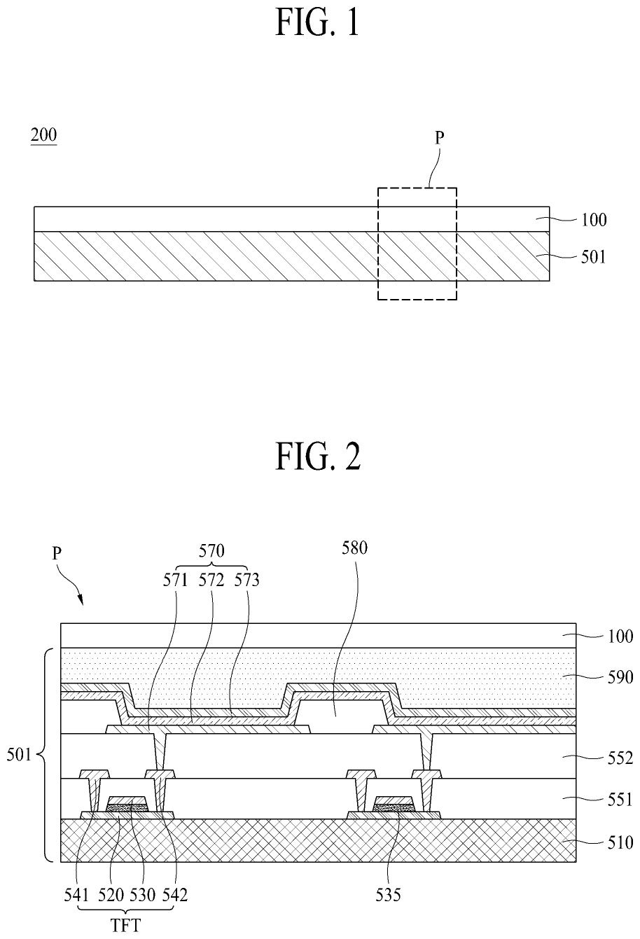

FIG. 1 is a cross-sectional view illustrating a part of a display device 200 according to another embodiment, and FIG. 2 is an enlarged cross-sectional view of “P” in FIG. 1.

Referring to FIG. 1, the display device 200 according to another embodiment of the present disclosure includes a display panel 501 and an optical film 100 on the display panel 501.

Referring to FIGS. 1 and 2, the display panel 501 includes a substrate 510, a thin film transistor TFT on the substrate 510, and an organic light-emitting device 570 connected to the thin film transistor TFT. The organic light-emitting device 570 includes a first electrode 571, an organic light-emitting layer 572 on the first electrode 571, and a second electrode 573 on the organic light-emitting layer 572. The display device 200 shown in FIGS. 1 and 2 is an organic light-emitting display device.

The substrate 510 may be formed of glass or plastic. Specifically, the substrate 510 may be formed of plastic such as a polymer resin or an optical film. Although not shown, a buffer layer may be disposed on the substrate 510.

The thin film transistor TFT is disposed on the substrate 510. The thin film transistor TFT includes a semiconductor layer 520, a gate electrode 530 that is insulated from the semiconductor layer 520 and at least partially overlaps the semiconductor layer 520, a source electrode 541 connected to the semiconductor layer 520, and a drain electrode 542 that is spaced apart from the source electrode 541 and is connected to the semiconductor layer 520.

Referring to FIG. 2, a gate insulating layer 535 is disposed between the gate electrode 530 and the semiconductor layer 520. An interlayer insulating layer 551 may be disposed on the gate electrode 530, and a source electrode 541 and a drain electrode 542 may be disposed on the interlayer insulating layer 551.

A planarization layer 552 is disposed on the thin film transistor TFT to planarize the top of the thin film transistor TFT.

A first electrode 571 is disposed on the planarization layer 552. The first electrode 571 is connected to the thin film transistor TFT through a contact hole provided in the planarization layer 552.

A bank layer 580 is disposed on the planarization layer 552 in a part of the first electrode 571 to define pixel areas or light-emitting areas. For example, the bank layer 580 is disposed in the form of a matrix at the boundaries between a plurality of pixels to define the respective pixel regions.

The organic light-emitting layer 572 is disposed on the first electrode 571. The organic light-emitting layer 572 may also be disposed on the bank layer 580. The organic light-emitting layer 572 may include one light-emitting layer, or two light-emitting layers stacked in a vertical direction. Light having any one color among red, green, and blue may be emitted from the organic light-emitting layer 572, and white light may be emitted therefrom.

The second electrode 573 is disposed on the organic light-emitting layer 572.

The first electrode 571, the organic light-emitting layer 572, and the second electrode 573 may be stacked to constitute the organic light-emitting device 570.

Although not shown, when the organic light-emitting layer 572 emits white light, each pixel may include a color filter for filtering the white light emitted from the organic light-emitting layer 572 based on a particular wavelength. The color filter is formed in the light path.

A thin-film encapsulation layer 590 may be disposed on the second electrode 573. The thin-film encapsulation layer 590 may include at least one organic layer and at least one inorganic layer, and the at least one organic layer and the at least one inorganic layer may be alternately disposed.

The optical film 100 is disposed on the display panel 501 having the stack structure described above.

Hereinafter, a method of manufacturing an optical film according to another embodiment of the present disclosure will be described in brief.

The method of manufacturing an optical film according to an embodiment of the present disclosure includes preparing a polymer resin, dissolving the polymer resin in a solvent to prepare a polymer resin solution, and producing an optical film using the polymer resin solution.

The preparation of the polymer resin may be performed by polymerizing monomers for forming the polymer resin, followed by imidization. The polymer resin may be prepared from monomer components including a first diamine-based compound, a second diamine-based compound, a dianhydride-based compound, and a dicarbonyl-based compound. There is no limitation as to the order or method of addition of the monomers in the present disclosure. For example, a dianhydride-based compound and a diamine-based compound may be sequentially added to a solution in which the diamine-based compound is dissolved, and the resulting mixture may be subjected to polymerization. Alternatively, in order to avoid randomness, the first diamine-based compound, the dianhydride-based compound, the second diamine-based compound, and the dicarbonyl-based compounds may be added in that order, or the second diamine-based compound, the dianhydride-based compound, the first diamine-based compound, and the dicarbonyl-based compound may be added in that order, followed by polymerization.

More specifically, the polymer resin may be prepared by polymerization and imidization of monomers including the first diamine-based compound, the second diamine-based compound, the dianhydride-based compound, and the dicarbonyl-based compound. The imide repeating unit may be prepared by polymerization and imidization of monomers including the first and second diamine-based compounds and the dianhydride-based compound. In addition, the amide repeating unit may be prepared by polymerization of monomers including the first and second diamine-based compounds and the dicarbonyl-based compound.

Accordingly, the polymer resin according to another embodiment of the present disclosure may have the imide repeating unit and the amide repeating unit.

The imide repeating unit and the amide repeating unit may be separately prepared and then copolymerized. Alternatively, an imide repeating unit may be prepared first, and then a dicarbonyl-based compound may be further added to prepare an amide repeating unit, or an amide repeating unit may be prepared first, and then a dianhydride-based compound may be further added to prepare an imide repeating unit. The polymer resin of the present disclosure is not limited as to the formation order of the repeating unit (the order in which the monomers are added).

According to another embodiment of the present disclosure, the dicarbonyl-based compound may be added in an amount of 80 mol % or more based on the total molar amount of the dianhydride-based compound and the dicarbonyl-based compound. Accordingly, the polymer resin of the present disclosure includes the amide repeating unit in an amount of 80% or more. Preferably, the dicarbonyl-based compound may be added in an amount of 95 mol % or more, more preferably, in an amount of 98 mol % or more, based on the total molar amount of the dianhydride-based compound and the dicarbonyl-based compound.

According to another embodiment of the present disclosure, the first diamine-based compound is 2,2′-bis(trifluoromethyl)benzidine (TFDB).

According to another embodiment of the present disclosure, the second diamine-based compound includes an aromatic diamine-based compound. Hereinafter, an explanation of the above configuration is omitted in order to avoid duplicate description.

2,2′-bis(trifluoromethyl)benzidine (TFDB) may be used as the first diamine-based compound, aromatic diamine-based compounds of Formula 1 described above may be used as the second diamine-based compound, and the compounds of Formula 2 described above may be used as the dianhydride-based compound. The compounds of Formula 3 described above may be used as the dicarbonyl-based compound.

According to another embodiment of the present disclosure, the aromatic diamine-based compound of the second diamine-based compound may have an ionization energy of 7.35 to 7.75 eV.

According to another embodiment of the present disclosure, the aromatic diamine-based compound of the second diamine-based compound may include at least one functional group selected from the group consisting of sulfonyl, carbonyl, methylene, propylene, and halogens.

According to another embodiment of the present disclosure, the aromatic diamine-based compound of the second diamine-based compound may include at least one selected from the group consisting of bis(3-aminophenyl)sulfone (3DDS), bis(4-aminophenyl)sulfone (4DDS), 2,2-bis(3-aminophenyl)hexafluoropropane (3,3′-6F), 2,2-bis(4-aminophenyl)hexafluoropropane (4,4′-6F), 4,4′-methylenedianiline (MDA), 3,3′-(dimethylamino)benzophenone (3,3′-CO), 4,4′-(dimethylamino)benzophenone (4,4′-CO), and tetrachloride benzidine (CIBZ).

According to another embodiment of the present disclosure, the ratio of the amount of the first diamine-based compound that is added to the amount of the second diamine-based compound that is added may be 95:5 to 65:35.

According to another embodiment of the present disclosure, the solvent for preparing the polymer resin solution may be, for example, a polar aprotic organic solvent such as N,N-dimethylacetamide (DMAc), N,N-dimethylformamide (DMF), 1-methyl-2-pyrrolidinone (NMP), m-cresol, tetrahydrofuran (THF), chloroform, methyl ethyl ketone (MEK), or a mixture thereof. However, the solvent according to an embodiment of the present disclosure is not limited thereto, and other solvents may be used.

Hereinafter, the present disclosure will be described in more detail with reference to exemplary examples. However, the following preparation examples and examples should not be construed as limiting the scope of the present disclosure.

### Example 1

313.34 g of N,N-dimethylacetamide (DMAc) was charged in a 500 mL reactor equipped with a stirrer, a nitrogen injector, a dropping funnel, a temperature controller, and a cooler while nitrogen was passed through the reactor. Then, the temperature of the reactor was adjusted to 25° C., 24.02 g (0.075 mol) of TFDB as a first diamine-based compound was dissolved therein, 6.21 g (0.025 mol) of bis(3-aminophenyl)sulfone (3DDS) as a second diamine-based compound was further dissolved therein, and the resulting solution was maintained at 25° C. 0.89 g (0.002 mol) of 6FDA was added to the resulting diamine-based compound solution and thoroughly dissolved therein by stirring for 2 hours. The reactor temperature was lowered to 10° C., 19.90 g (0.098 mol) of terephthaloyl chloride (TPC) was added thereto, completely dissolved, and reacted for 1 hour, and then the temperature was elevated to 25° C. 0.35 g of pyridine and 0.45 g of acetic anhydride were added to the resulting reaction solution and stirred at 80° C. for 30 minutes, and excess methanol was added dropwise to obtain a polyamide-imide powder. The powder was filtered under reduced pressure, dried, and dissolved again in DMAc to prepare a polymer resin solution having a solid concentration of 14 wt %.

The obtained polymer resin solution was cast. A casting substrate was used for casting. There is no particular limitation as to the type of the casting substrate. As the casting substrate, a glass substrate, a stainless steel (SUS) substrate, a Teflon substrate, or the like may be used. According to an embodiment of the present disclosure, an organic substrate may be used as the casting substrate.

Specifically, the obtained polymer resin solution was applied onto a glass substrate, cast, and dried with hot air at 80° C. for 20 minutes and at 120° C. for 20 minutes to produce a film. Then, the produced film was peeled off of the glass substrate and fixed to a frame with a pin.

The frame to which the film was fixed was placed in an oven and then was dried with hot air at a constant temperature of 270° C. for 10 minutes. As a result, an optical film having a thickness of 50 μm was completed.

### Examples 2 to 12

Optical films of Examples 2 to 12 were manufactured in the same manner as in Example 1, except that the addition amount of the first diamine (TFDB), the type and addition amount of the second diamine, the type and addition amount of the dianhydride-based compound, and the type and addition amount of the dicarbonyl-based compound were changed.

Details of the addition amount of the first diamine (TFDB), the type and addition amount of the second diamine, the type and addition amount of the dianhydride-based compound, and the type and addition amount of the dicarbonyl-based compound of Examples 1 to 12 are shown in Table 1 below.

### Example 13

A film was produced in the same manner as in Example 1, except that the addition amount of the first diamine (TFDB), the type and addition amount of the second diamine, the type and addition amount of the dianhydride-based compound, and the type and addition amount of the dicarbonyl-based compound were changed. Then, the produced film was peeled off of the glass substrate and fixed to a frame with a pin. The frame to which the film was fixed was placed in an oven and then was dried with hot air at a constant temperature of 250° C. for 10 minutes. As a result, an optical film having a thickness of 50 μm of Example 13 was completed.

Details of the addition amount of the first diamine (TFDB), the type and addition amount of the second diamine, the type and addition amount of the dianhydride-based compound, and the type and addition amount of the dicarbonyl-based compound of Example 13 are shown in Table 1 below.

### Comparative Examples 1 to 3

The optical films of Comparative Examples 1 to 3 were manufactured in the same manner as in Example 1, except that the addition amount of the first diamine (TFDB), the type and addition amount of the second diamine, the type and addition amount of the dianhydride-based compound, and the type and addition amount of the dicarbonyl-based compound were changed.

Details of the addition amount of the first diamine (TFDB), the type and addition amount of the second diamine, the type and addition amount of the dianhydride-based compound, and the type and addition amount of the dicarbonyl-based compound of Comparative Examples 1 to 3 are shown in Table 1 below.

### Comparative Examples 4 and 5

The optical films of Comparative Examples 4 and 5 were manufactured in the same manner as in Example 1, except that the addition amount of the first diamine (TFDB), the type and addition amount of the second diamine, and the type and addition amount of the dicarbonyl-based compound were changed. In Comparative Examples 4 and 5, no dianhydride-based compound was used and thus a step of purifying a chemical curing agent and methanol was omitted.

Details of the addition amount of the first diamine (TFDB), the type and addition amount of the second diamine, and the type and addition amount of the dicarbonyl-based compound of Comparative Examples 4 and 5 are shown in Table 1 below.

TABLE 1

| | Type and | Type and | | Type and | Type and | |
|---|---|---|---|---|---|---|
| | addition amount | addition amount | Ionization | addition | addition | |
| | of first | of second | energy of second | amount of | amount of | |
| | diamine-based | diamine-based | diamine-based | dianhydride- | dicarbonyl-based | Film |
| | compound | compound | compound | based compound | compound | thickness |
| Item | (mol %) | (mol %) | (eV) | (mol %) | (mol %) | (μm) |
| Example 1 | TFDB: 75 | 3DDS: 25 | 7.68 | 6FDA: 2 | TPC: 98 | 50 |
| Example 2 | TFDB: 80 | 3DDS: 20 | 7.68 | 6FDA: 5 | TPC: 95 | 50 |
| Example 3 | TFDB: 75 | 3DDS: 25 | 7.68 | 6FDA: 5 | TPC: 95 | 50 |
| Example 4 | TFDB: 75 | 3DDS: 25 | 7.68 | 6FDA: 5 | BPDC: 95 | 50 |
| Example 5 | TFDB: 90 | 4DDS: 10 | 7.50 | 6FDA: 5 | TPC: 95 | 50 |
| Example 6 | TFDB: 85 | 4DDS: 15 | 7.50 | 6FDA: 5 | TPC: 95 | 50 |
| Example 7 | TFDB: 85 | 4DDS: 15 | 7.50 | 6FDA: 2 | TPC: 98 | 50 |
| Example 8 | TFDB: 90 | 4DDS: 10 | 7.50 | 6FDA: 10 | TPC: 90 | 50 |
| Example 9 | TFDB: 80 | 4DDS: 20 | 7.50 | 6FDA: 20 | TPC: 80 | 50 |
| Example 10 | TFDB: 75 | 3,3′-6F: 25 | 7.36 | 6FDA: 2 | TPC: 98 | 50 |
| Example 11 | TFDB: 90 | 4,4′-6F: 10 | 7.41 | 6FDA: 5 | TPC: 95 | 50 |
| Example 12 | TFDB: 65 | 3DDS: 35 | 7.68 | BPDA: 5 | TPC: 95 | 50 |
| Example 13 | TFDB: 70 | 3DDS: 30 | 7.68 | CBDA: 15 | TPC: 85 | 50 |
| Comparative | TFDB: 75 | pPDA: 25 | 7.03 | 6FDA: 2 | TPC: 98 | (Impossible |
| Example 1 | | | | | | polymerization) |
| Comparative | TFDB: 90 | 8FODA: 10 | 8.04 | 6FDA: 5 | TPC: 95 | 50 |
| Example 2 | | | | | | |
| Comparative | TFDB: 100 | — | — | 6FDA: 5 | TPC: 95 | 50 |
| Example 3 | | | | | | |
| Comparative | TFDB: 100 | — | — | — | TPC: 100 | (Impossible |
| Example 4 | | | | | | polymerization) |
| Comparative | TFDB: 40 | 3DDS: 60 | 7.68 | — | TPC: 100 | 50 |
| Example 5 | | | | | | |

3DDS: Bis(3-aminophenyl)sulfone
4DDS: Bis(4-aminophenyl)sulfone
3,3′-6F: 2,2-bis(3-aminophenyl)hexafluoropropane
4,4′-6F: 2,2-bis(4-aminophenyl)hexafluoropropane
pPDA: Para-phenylene diamine
8FODA: Oxy-4,4′-bis(2,3,5,6-tetrafluoroaniline)
TPC: Terephthaloyl chloride
BPDC: 4,4′-biphenyl dicarbonyl chloride
CBDA: 1,2,3,4-cyclobutanetetracarboxylic dianhydride

### Measurement Example

The following measurements were performed on the polymer resins and films produced in Examples 1 to 13 and Comparative Examples 1 to 5.
1) Weight average molecular weight of polymer resin: the weight average molecular weight of the polymer resin was measured under the following conditions using a GPC (Alliance e2695/2414 RID, Waters).
Detector: 2414 RID, Waters
Mobile phase: 10 mM LiBr in DMAc
Sample concentration: 0.25 (w/w) % in DMAc
Column and detector temperature: 50° C.
Flow Rate: 1.0 ml/min
2) Yellowness index (Y.I.): the yellowness index was measured using a spectrophotometer (CM-3700D, KONICA MINOLTA) in accordance with the ASTM E313 standard.
3) Light transmittance (%): Average optical transmittance at a wavelength of 360 to 740 nm was measured using a spectrophotometer (CM-3700D, KONICA MINOLTA).
4) Haze: Haze was determined by cutting the produced optical film to a sample having a size of 50 mm×50 mm, performing measurement five times using a haze meter (model name: HM-150, produced by Murakami Color Research Laboratory) in accordance with ASTM D1003, and taking the average of the five values as the haze of the optical film.

The measurement results are shown in Table 2 below.

TABLE 2

| | Weight | | Light | |
|---|---|---|---|---|
| | average | | trans- | |
| | molecular | Yellowness | mittance | Haze |
| Item | weight of resin | index (Y.I.) | (%) | (%) |
| Example 1 | 330,000 | 1.92 | 88.83 | 0.4 |
| Example 2 | 350,000 | 1.88 | 88.99 | 0.3 |
| Example 3 | 320,000 | 1.79 | 89.04 | 0.3 |
| Example 4 | 310,000 | 1.83 | 89.01 | 0.3 |
| Example 5 | 300,000 | 1.93 | 89.02 | 0.3 |
| Example 6 | 280,000 | 1.73 | 89.17 | 0.2 |
| Example 7 | 310,000 | 1.81 | 89.09 | 0.3 |
| Example 8 | 290,000 | 1.67 | 89.21 | 0.2 |
| Example 9 | 290,000 | 1.55 | 89.27 | 0.2 |
| Example 10 | 330,000 | 1.89 | 88.89 | 0.3 |
| Example 11 | 310,000 | 1.90 | 89.15 | 0.2 |
| Example 12 | 250,000 | 2.07 | 88.70 | 0.3 |
| Example 13 | 300,000 | 2.15 | 89.06 | 0.2 |
| Comparative | Impossible | (Impossible | (Impossible | (Impossible |
| Example 1 | measurement | poly- | poly- | poly- |
| | | merization) | merization) | merization) |
| Comparative | 120,000 | 6.54 | 88.22 | 0.8 |
| Example 2 | | | | |
| Comparative | 440,000 | 27.9 | 58.4 | 49.6 |
| Example 3 | | | | |
| Comparative | Impossible | (Impossible | (Impossible | (Impossible |
| Example 4 | measurement | poly- | poly- | poly- |
| | | merization) | merization) | merization) |
| Comparative | 240,000 | 4.68 | 87.78 | 0.3 |
| Example 5 | | | | |

As can be seen from the results of measurement of Table 2, Examples 1 to 13 of the present disclosure had high weight average molecular weight and excellent yellowness, light transmittance, and haze.

However, in Comparative Examples 1 and 4, it was impossible to produce a film due to the gelation of the dicarbonyl-based compound. In Comparative Example 2, the resin had a low weight average molecular weight, yellowness index and haze were high, light transmittance was low, and thus visibility was poor. In Comparative Example 3, the resin had a high weight average molecular weight, but yellowness index and haze were remarkably high, and light transmittance was remarkably low. In Comparative Example 5, the resin had a high weight average molecular weight, but yellowness index was high and light transmittance was low.

### EXPLANATION OF REFERENCE NUMERALS

100: Optical film
200: Display device
501: Display panel

1. An optical film comprising a polymer resin comprising a first repeating unit, a second repeating unit, a third repeating unit, and a fourth repeating unit,
wherein the first repeating unit is an imide repeating unit derived from a first diamine-based compound and a dianhydride-based compound,
the second repeating unit is an imide repeating unit derived from a second diamine-based compound and the dianhydride-based compound,
the third repeating unit is an amide repeating unit derived from the first diamine-based compound and a dicarbonyl-based compound, and
the fourth repeating unit is an amide repeating unit derived from the second diamine-based compound and the dicarbonyl-based compound,
wherein the first diamine-based compound is 2,2′-bis(trifluoromethyl)benzidine (TFDB) and the second diamine-based compound comprises an aromatic diamine-based compound, and
a sum of numbers of the amide repeating units including the third and fourth repeating units is 80% or more of a total number of repeating units including the first to fourth repeating units.

2. The optical film according to claim 1, wherein the aromatic diamine-based compound of the second diamine-based compound has an ionization energy of 7.35 to 7.75 eV.

3. The optical film according to claim 1, wherein the aromatic diamine-based compound of the second diamine-based compound comprises at least one functional group selected from the group consisting of sulfonyl, carbonyl, methylene, propylene, and halogens.

4. The optical film according to claim 1, wherein the aromatic diamine-based compound of the second diamine-based compound comprises at least one selected from the group consisting of bis(3-aminophenyl)sulfone (3DDS), bis(4-aminophenyl)sulfone (4DDS), 2,2-bis(3-aminophenyl)hexafluoropropane (3,3′-6F), 2,2-bis(4-aminophenyl)hexafluoropropane (4,4′-6F), 4,4′-methylenedianiline (MDA), 3,3′-(dimethylamino)benzophenone, 4,4′-(dimethylamino)benzophenone, and tetrachloride benzidine (CIBZ).

5. The optical film according to claim 1, wherein a ratio of a number of repeating units derived from the first diamine-based compound to a number of repeating units derived from the second diamine-based compound is 95:5 to 65:35.

6. The optical film according to claim 1, wherein the polymer resin has a weight average molecular weight (Mw) of 200,000 to 500,000.

7. The optical film according to claim 1, wherein the optical film has a yellowness index (Y.I.) of 3 or less based on a thickness of 50 μm.

8. The optical film according to claim 1, wherein the optical film has a light transmittance of 88% or more based on a thickness of 50 μm.

9. The optical film according to claim 1, wherein the optical film has a haze of 0.5% or less based on a thickness of 50 μm.

10. A display device comprising:
a display panel; and
the optical film according to claim 1 disposed on the display panel.
